(19) United States
(12) Patent Application Publication
(10) Pub. No.: US 2026/0282773 A1
(43) Pub. Date: Sep. 17, 2026

(54) METHODS OF MANUFACTURING SEMICONDUCTOR DEVICES

(71) Applicant: Applied Materials, Inc., Santa Clara, CA (US)

(72) Inventors: Yuxin Wang, Fremont, CA (US); Ying-Bing Jiang, San Jose, CA (US); Joung Joo Lee, San Jose, CA (US)

(73) Assignee: Applied Materials, Inc., Santa Clara, CA (US)

(21) Appl. No.: 19/078,769

(22) Filed: Mar. 13, 2025

(51) Int. Cl. H01L 21/3205; H01L 21/02

(52) U.S. Cl. CPC H10P 14/414; H10P 14/6334; H10P 14/693; H10P 14/6932; H10P 14/6934

(57) ABSTRACT

Methods of manufacturing semiconductor devices are described. The methods include depositing a molybdenum silicide layer directly on a substrate; depositing an interfacial layer directly on the molybdenum silicide layer; and depositing a metal nitride layer directly on the interfacial layer. The interfacial layer includes a metal silicide having a formula of MSiₓ, where M is a metal and x is an integer in a range of from 1 to 3 or a metal silicon nitride having a formula MSiN where M is the metal.

### TECHNICAL FIELD

Embodiments of the disclosure generally relate to the manufacture of semiconductor devices. More particularly, embodiments of the disclosure are directed to methods of manufacturing logic devices and/or memory devices.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Generally, front-end of line (FEOL) refers to the first portion of integrated circuit fabrication, including transistor fabrication, middle-of-line (MOL) connects the transistor and interconnect parts of a chip using a series of contact structures, and back-end of line (BEOL) refers to a series of process steps after transistor fabrication through completion of a wafer.

Metal silicides have been widely used as materials for contacts, for example, in various semiconductor device structures. The main advantage metal silicide contacts offer over contacts that do not include metal silicide is a higher device performance owing to lower parasitic resistance. In many semiconductor device applications, including contact applications, a metal nitride layer on a metal silicide layer, such as molybdenum silicide (MoSi), on a silicon substrate has been used. However, it has been found that silicon diffusion from the molybdenum silicide (MoSi) layer and nitrogen diffusion from the metal nitride layer form a layer comprised of silicon nitride between the molybdenum silicide (MoSi) layer and the metal nitride layer, which can be harmful to electrical properties of the semiconductor device. It has also been found that varying the processing conditions for deposition of the metal nitride layer does not prevent formation of the silicon nitride layer between the molybdenum silicide (MoSi) layer and the metal nitride layer. Additionally, it has been found that varying the thickness of the deposited metal nitride layer also does not prevent formation of the silicon nitride layer between the molybdenum silicide (MoSi) layer and the metal nitride layer.

It has been found that varying the thickness, quality, and growth condition of the deposited molybdenum silicide (MoSi) layer also does not prevent formation of the silicon nitride layer between the molybdenum silicide (MoSi) layer and the metal nitride layer.

Accordingly, there is a need for improving the interface between the metal silicide (e.g., molybdenum silicide (MoSi)) and a metal nitride layer thereon.

### SUMMARY

One or more embodiments of the disclosure are directed to a method of manufacturing a semiconductor device. In one or more embodiments, the method comprises: depositing a molybdenum silicide (MoSi) layer directly on a substrate; depositing an interfacial layer directly on the molybdenum silicide (MoSi) layer, the interfacial layer comprising a metal silicide having a formula of MSiₓ, where M is a metal and x is an integer in a range of from 1 to 3 or a metal silicon nitride having a formula MSiN where M is the metal; and depositing a metal nitride layer directly on the interfacial layer.

Additional embodiments of the disclosure are directed to a method of manufacturing a semiconductor device. In one or more embodiments, the method comprises: depositing a molybdenum silicide (MoSi) layer directly on a substrate; depositing an interfacial layer directly on the molybdenum silicide (MoSi) layer, the interfacial layer comprising a metal silicide having a formula of MSiₓ, where M is a metal and x is an integer in a range of from 1 to 3 or a metal silicon nitride having a formula MSiN where M is the metal; and depositing a metal nitride layer directly on the interfacial layer.

Further embodiments of the disclosure are directed to a non-transitory computer readable medium including instructions, that, when executed by a controller of a processing system, causes the processing system to: deposit a molybdenum silicide (MoSi) layer directly on a substrate; deposit an interfacial layer directly on the molybdenum silicide (MoSi) layer, the interfacial layer comprising a metal silicide having a formula of MSiₓ, where M is a metal and x is an integer in a range of from 1 to 3 or a metal silicon nitride having a formula MSiN where M is the metal; and deposit a metal nitride layer directly on the interfacial layer.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method in accordance with one or more embodiments of the disclosure;

FIG. 2A illustrates a schematic cross-sectional view of a substrate having a molybdenum silicide layer deposited directly thereon, an interfacial layer deposited directly on the molybdenum silicide layer, and a metal nitride layer deposited directly on the interfacial layer, in accordance with one or more embodiments of the disclosure;

FIG. 2B illustrates a schematic cross-sectional view of a substrate including a top surface and a feature having sidewalls and a bottom surface in accordance with one or more embodiments of the disclosure;

FIG. 2C illustrates a cross-sectional schematic view of the substrate of FIG. 2B after deposition of a molybdenum silicide layer on the top surface of the substrate, on the sidewalls, and on the bottom surface in accordance with one or more embodiments of the disclosure;

FIG. 2D illustrates a cross-sectional schematic view of the substrate of FIG. 2C after deposition of an interfacial layer directly on the molybdenum silicide layer in accordance with one or more embodiments of the disclosure; and

FIG. 2E illustrates a cross-sectional schematic view of the substrate of FIG. 2D after deposition of a metal nitride layer directly on the interfacial layer in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the structure (e.g., substrate) in use or operation in addition to the orientation depicted in the Figures. For example, if the substrate in the Figures is turned over, elements described as “below” or “beneath” other elements would then be oriented “above” the other elements. Thus, the exemplary term “below” may encompass both an orientation of above and below. The substrate may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed includes materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing an inert gas over the substrate. In one or more embodiments, the inert gas is selected from one or more of nitrogen (N₂), helium (He), and argon (Ar). In some embodiments, the first reactive species is purged from the reaction chamber for a time duration in a range of from 0.1 seconds to 30 seconds, for example, before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, an inert gas, such as argon, is introduced into the processing chamber to purge the reaction zone or otherwise remove any residual reactive species or reaction by-products from the reaction zone. Alternatively, the inert gas may flow continuously throughout the deposition process so that only the inert gas flows during the time delay between pulses of reactive species. The reactive species are alternatively pulsed until a desired layer or layer thickness is formed on the substrate surface. In either scenario, the ALD process of pulsing compound A, inert gas, compound B, and inert gas is a cycle. A cycle can start with either compound A or compound B and continue the respective order of the cycle until achieving a layer with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Generally, front-end of line (FEOL) refers to the first portion of integrated circuit fabrication, including transistor fabrication, middle-of-line (MOL) connects the transistor and interconnect parts of a chip using a series of contact structures, and back-end of line (BEOL) refers to a series of process steps after transistor fabrication through completion of a wafer. The methods described herein can advantageously be used in MOL and/or BEOL processes.

Transistors are circuit components or elements that are often formed on semiconductor devices. Many transistors may be formed on a semiconductor device in addition to capacitors, inductors, resistors, diodes, conductive lines, or other elements, depending upon the circuit design. The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals.

Generally, a transistor includes a gate formed between source and drain regions. The source and drain regions may include a doped region of a substrate and may exhibit a doping profile suitable for a particular application. The gate is positioned over the channel region and may include a gate dielectric interposed between a gate electrode and the channel region in the substrate.

As used herein, the term “field effect transistor” or “FET” refers to a transistor that uses an electric field to control the electrical behavior of the device. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated I_{S} and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET) and is used in integrated circuits and high-speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both be of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p-type substrate region. If the MOSFET is a p-channel or pMOS FET, then the source and drain are p+ regions and the body is a n-type substrate region. The source is so named because it is the source of the charge carriers (electrons for n-channel, holes for p-channel) that flow through the channel; similarly, the drain is where the charge carriers leave the channel.

A nMOS FET is made up of a n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode, and saturation. Circuits with NMOS logic gates dissipate static power when the circuit is idling, since DC current flows through the logic gate when the output is low.

A pMOS FET is made up of p-type source and drain and a n-type substrate. When a positive voltage is applied between the source and the gate (negative voltage between gate and source), a p-type channel is formed between the source and the drain with opposite polarities. A current is carried by holes from source to the drain through an induced p-type channel. A high voltage on the gate will cause a PMOS not to conduct, while a low voltage on the gate will cause it to conduct. Logic gates and other digital devices implemented using PMOS are said have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices. Furthermore, NMOS ICs would be smaller than PMOS ICs (that give the same functionality), since the NMOS can provide one-half of the impedance provided by a PMOS (which has the same geometry and operating conditions).

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

A DRAM device is formed of an array of DRAM cells. The rows on access transistors are linked by word lines, and the transistor inputs/outputs are linked by bit lines. Historically, DRAM capacitors have evolved from planar polysilicon-oxide-substrate plate capacitors to 3-D structures which have diverged into “stack” capacitors with both plates above the substrate, and “trench” capacitors using an etched cavity in the substrate as the common plate.

Metal silicides have been widely used as materials for contacts, for example, in various semiconductor device structures. The main advantage metal silicide contacts offer over contacts that do not include metal silicide is a higher device performance owing to lower parasitic resistance. In many semiconductor device applications, including contact applications, a metal nitride layer on a metal silicide layer, such as molybdenum silicide (MoSi), on a silicon substrate has been used. However, it has been found that silicon diffusion from the molybdenum silicide (MoSi) layer and nitrogen diffusion from the metal nitride layer form a layer comprised of silicon nitride between the molybdenum silicide (MoSi) layer and the metal nitride layer, which can be harmful to electrical properties of the semiconductor device. It has also been found that varying the processing conditions for deposition of the metal nitride layer does not prevent formation of the silicon nitride layer between the molybdenum silicide (MoSi) layer and the metal nitride layer. Additionally, it has been found that varying the thickness of the deposited metal nitride layer also does not prevent formation of the silicon nitride layer between the molybdenum silicide (MoSi) layer and the metal nitride layer.

It has been found that varying the thickness, quality, and growth condition of the deposited molybdenum silicide (MoSi) layer also does not prevent formation of the silicon nitride layer between the molybdenum silicide (MoSi) layer and the metal nitride layer.

Embodiments of the disclosure are directed to methods of manufacturing semiconductor devices, including, but not limited to, logic devices and/or memory devices. Some embodiments are directed methods of manufacturing “PMOS” or “PFET” structures and/or “NMOS” or “NFET” structures. Some embodiments are directed to methods of manufacturing NAND or vertical(V)-NAND (i.e., 3D-NAND) devices. Some embodiments are directed to methods of manufacturing DRAM devices, including 3D-DRAM devices. Some embodiments are directed to methods of manufacturing Fin field effect transistors (FinFET). Some embodiments are directed to methods of manufacturing gate-all-around (GAA) transistors.

The methods described herein are advantageously configured to improve the interface between the metal silicide (e.g., molybdenum silicide (MoSi)) and a metal nitride layer thereon, compared to currently employed methods of depositing a metal nitride layer directly on a metal silicide layer, such as molybdenum silicide (MoSi), on a silicon substrate. Advantageously, the methods described herein are configured to prevent formation of a silicon nitride layer between a molybdenum silicide (MoSi) layer and a metal nitride layer.

The methods include depositing a molybdenum silicide layer directly on a substrate; depositing an interfacial layer directly on the molybdenum silicide layer; and depositing a metal nitride layer directly on the interfacial layer. The interfacial layer includes a metal silicide having a formula of MSiₓ, where M is a metal and x is an integer in a range of from 1 to 3 or a metal silicon nitride having a formula MSiN where M is the metal.

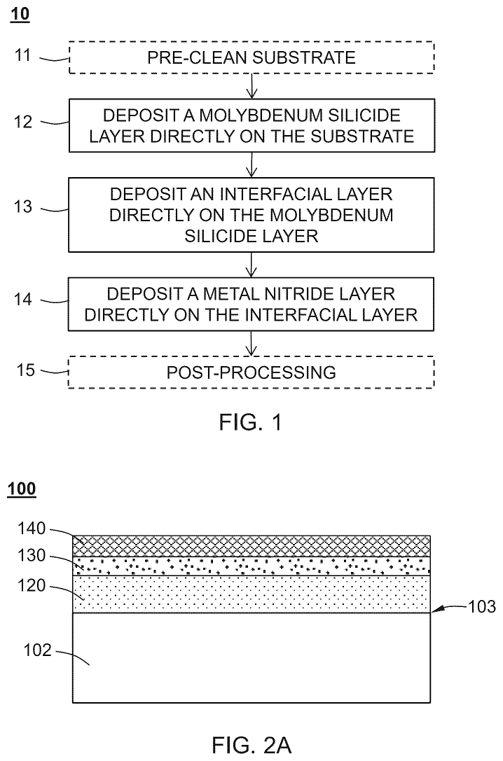

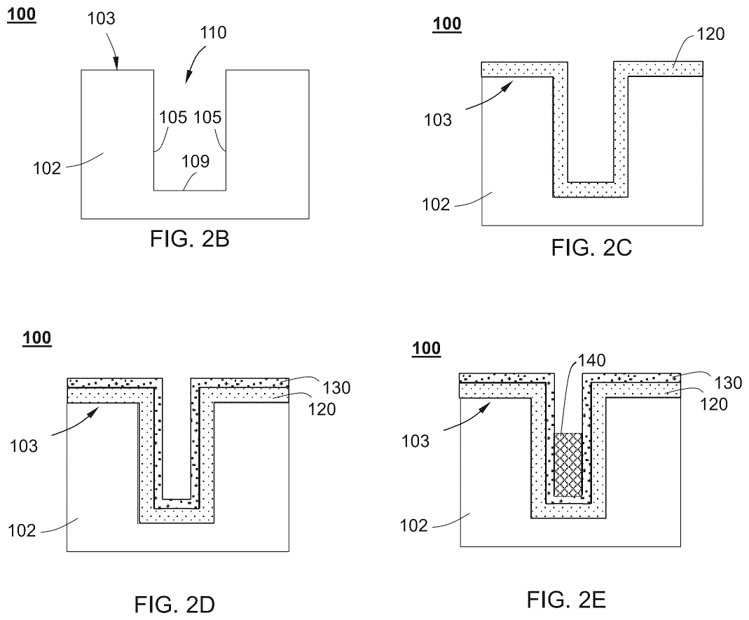

The methods of the present disclosure are described with reference to FIGS. 1 and 2A-2E. FIG. 1 illustrates a process flow diagram of a method 10. FIG. 2A illustrates a schematic cross-sectional view of a device 100 including a substrate 102 processed in accordance with the method 10. FIGS. 2B-2E illustrate schematic cross-sectional views of stages of processing the substrate 102 having a top surface 103 and at least one feature 110 including sidewalls 105 and a bottom surface 109 in accordance with the method 10.

The methods of the present disclosure (e.g., the method 10), which are described with reference to FIGS. 1 and 2A-2E, are methods of manufacturing semiconductor devices (i.e., the device 100), or part of a fabrication process used in the manufacture of semiconductor devices (i.e., the device 100). In one or more embodiments, the device 100 is a semiconductor device. In one or more embodiments, the device 100 is a logic device. In one or more embodiments, the device 100 is a memory device. In one or more embodiments, the device 100 is a “PMOS” or “PFET” structure. In one or more embodiments, the device 100 is a “NMOS” or “NFET” structure. In one or more embodiments, the device 100 is a NAND device. In one or more embodiments, the device 100 is a vertical(V)-NAND (i.e., 3D-NAND) device. In one or more embodiments, the device 100 is a DRAM device. In one or more embodiments, the device 100 is a 3D-DRAM device. In one or more embodiments, the device 100 is a Fin field effect transistor (FinFET). In one or more embodiments, the device 100 is a gate-all-around (GAA) transistor.

In one or more embodiments, the method 10 optionally includes pre-cleaning the substrate 102 at operation 11. Operation 11 is denoted as optional in FIG. 1 by using the dashed outline in the process flow diagram. In one or more embodiments, keeping the pre-cleaning process under vacuum ensures that no oxide is introduced/formed on the substrate 102 during the method 10. In one or more embodiments, pre-cleaning the substrate 102 is configured to remove native oxides from one or more surfaces of the substrate 102.

The pre-cleaning process can be any suitable process. In some embodiments, the pre-cleaning process is configured to remove metal oxide from the one or more surfaces and maintains the integrity of the dielectric surface. As used herein, the term “substrate 102” can be used to refer to a substrate and/or a pre-cleaned substrate, unless the context clearly indicates otherwise.

The method 10 can be performed at any suitable processing conditions, and the processing conditions may vary based upon the application in which the substrate 102 is used, unless otherwise specifically indicated.

In one or more embodiments, the method 10 is performed at a temperature in a range of from 20° C. to 600° C. In one or more embodiments, the method 10 is performed at a pressure in a range of from 5 torr to 50 Torr. In some embodiments, one or more operations of the method 10 are performed in situ in an integrated processing system. In some embodiments, each operation of the method 10 are performed in situ in an integrated processing system.

The method 10 includes, at operation 12, depositing a molybdenum silicide (MoSi) layer 120 on the substrate 102. In FIGS. 2A-2E, the substrate 102 includes a top surface 103. In FIGS. 2B-2E, the substrate 102 includes at least one feature 110. The at least one feature 110 has sidewalls 105 and a bottom surface 109.

The sidewalls 105 and the bottom surface 109 may comprise any suitable material, respectively. In one or more embodiments, the sidewalls 105 comprise a dielectric material. The dielectric material can include any suitable dielectric material. In one or more embodiments, the sidewalls 105 comprise a low-κ dielectric material. In one or more embodiments, the sidewalls 105 comprise silicon oxide. In one or more embodiments, the bottom surface 109 comprises a metallic material. The metallic material can include any suitable metallic material. In one or more embodiments, the bottom surface 109 comprises one or more of ruthenium (Ru), copper (Cu), cobalt (cobalt), molybdenum (Mo), tantalum (Ta), or tungsten (W). In one or more embodiments, the bottom surface 109 comprises one or more of titanium silicide (TiSi), titanium silicon nitride (TiSiN), titanium nitride (TiN), or molybdenum silicide (MoSi).

The Figures show a substrate 102 having a single feature for illustrative purposes; however, those skilled in the art will understand that there can be more than one feature.

As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 1:1, 2:1, 5:1, 10:1, 15:1, 20:1, 25:1, 30:1, 35:1, 40:1, 50:1, 100:1, or 500:1.

In some embodiments, the at least one feature 110 defines a cylindrical via that, when filled with metal, transfers current between layers, and lines that transfer current within the same device layer. In one or more embodiments, the at least one feature 110 is a trench having an aspect ratio in a range of from 1:1 to 500:1.

The molybdenum silicide (MoSi) layer 120 can be deposited on or directly on the substrate 102 by any suitable deposition technique, including, but not limited to physical vapor deposition (PVD), chemical vapor deposition (CVD), or atomic layer deposition (ALD). In some embodiments, the molybdenum silicide (MoSi) layer 120 is deposited by physical vapor deposition (PVD). In some embodiments, the molybdenum silicide (MoSi) layer 120 is deposited by chemical vapor deposition (CVD). In some embodiments, the molybdenum silicide (MoSi) layer 120 is deposited by atomic layer deposition (ALD). As used herein, a layer which is “conformal” (inclusive of “conformally deposited”) refers to a layer where the thickness is about the same throughout (e.g., on the top surface 103, middle and bottom of sidewalls 105 and on the bottom surface 109). A layer which is substantially conformal varies in thickness by less than or equal to about 5%, 2%, 1% or 0.5%.

In some embodiments, the molybdenum silicide (MoSi) layer 120 is deposited by a thermal process without the use of plasma.

In some embodiments, the molybdenum silicide (MoSi) layer 120 is deposited by thermal chemical vapor deposition (CVD), i.e., without the use of plasma. In some embodiments, the molybdenum silicide (MoSi) layer 120 is deposited by pulsed thermal chemical vapor deposition (CVD), where one of the molybdenum-containing precursor and the silicon-containing reactant used to form the molybdenum silicide (MoSi) layer 120 is pulsed constantly, and the other of the molybdenum-containing precursor and the silicon-containing reactant is pulsed at a regular interval (i.e., pulsed intermittently).

In some embodiments, the molybdenum silicide (MoSi) layer 120 is deposited by thermal atomic layer deposition (ALD), i.e., without the use of plasma. In some embodiments, the molybdenum silicide (MoSi) layer 120 is deposited by pulsed thermal atomic layer deposition (ALD), where one of the molybdenum-containing precursor and the silicon-containing reactant used to form the molybdenum silicide (MoSi) layer 120 is pulsed constantly, and the other of the molybdenum-containing precursor and the silicon-containing reactant is pulsed at a regular interval (i.e., pulsed intermittently).

Any suitable molybdenum-containing precursor(s) and any suitable silicon-containing reactant(s) can be used to deposit the molybdenum silicide (MoSi) layer 120. In one or more embodiments, the molybdenum-containing precursor comprises molybdenum pentachloride (MoCl₅). In one or more embodiments, the silicon-containing reactant comprises a silane.

The molybdenum silicide (MoSi) layer 120 can have any suitable thickness. In some embodiments, the molybdenum silicide (MoSi) layer 120 has a thickness in a range of from 10 Angstroms to 100 Angstroms.

The molybdenum silicide (MoSi) layer 120 can be deposited at any suitable processing conditions, and the processing conditions may vary depending on the particular application in which the molybdenum silicide (MoSi) layer 120 is used for.

The method 10 includes, at operation 13, depositing an interfacial layer 130 on or directly on the molybdenum silicide (MoSi) layer 120. The interfacial layer 130 can be deposited by any suitable deposition technique, including, but not limited to physical vapor deposition (PVD), chemical vapor deposition (CVD), or atomic layer deposition (ALD). In some embodiments, the interfacial layer 130 is deposited by chemical vapor deposition (CVD). In some embodiments, the interfacial layer 130 is deposited by atomic layer deposition (ALD). In some embodiments, the interfacial layer 130 is conformally deposited by atomic layer deposition (ALD).

In some embodiments, the interfacial layer 130 is deposited by a thermal process without the use of plasma.

In some embodiments, the interfacial layer 130 is deposited by thermal chemical vapor deposition (CVD), i.e., without the use of plasma. In some embodiments, the interfacial layer 130 is deposited by pulsed thermal chemical vapor deposition (CVD), where at least one of the metal-containing precursor and the silicon-containing reactant (and the nitrogen-containing reactant if the interfacial layer 130 comprises the metal silicon nitride) used to form the interfacial layer 130 is pulsed constantly, and at least one of the other of the metal-containing precursor and the silicon-containing reactant (and the nitrogen-containing reactant if the interfacial layer 130 comprises the metal silicon nitride) is pulsed at a regular interval (i.e., pulsed intermittently).

In some embodiments, the interfacial layer 130 is deposited by thermal atomic layer deposition (ALD), i.e., without the use of plasma. In some embodiments, the interfacial layer 130 is deposited by pulsed thermal atomic layer deposition (ALD), where at least one of the metal-containing precursor and the silicon-containing reactant (and the nitrogen-containing reactant if the interfacial layer 130 comprises the metal silicon nitride) used to form the interfacial layer 130 is pulsed constantly, and at least one of the other of the metal-containing precursor and the silicon-containing reactant (and the nitrogen-containing reactant if the interfacial layer 130 comprises the metal silicon nitride) is pulsed at a regular interval (i.e., pulsed intermittently).

The interfacial layer 130 can be deposited at any suitable processing conditions, and the processing conditions may vary depending on the particular application in which the interfacial layer 130 is used for.

The interfacial layer 130 can have any suitable thickness. In some embodiments, the interfacial layer 130 has a thickness in a range of from 20 Angstroms to 100 Angstroms.

In one or more embodiments, the interfacial layer 130 comprises, consists essentially of, or consists of a metal silicide or a metal silicon nitride. In one or more embodiments, the interfacial layer 130 comprises, consists essentially of, or consists of a metal silicide. In one or more embodiments, the interfacial layer 130 comprises, consists essentially of, or consists of a metal silicon nitride.

The metal silicide can be any compound that includes at least one metal atom and at least one silicon atom. In one or more embodiments, the at least one meatal atom comprises one or more of molybdenum (Mo), tungsten (W), cobalt (Co), titanium (Ti), zirconium (Zr), or hafnium (Hf).

In one or more embodiments, the metal silicide has a formula of MSiₓ, where M is a metal and x is an integer in a range of from 1 to 3. In some embodiments, x is 1. In some embodiments, x is 2. In some embodiments, x is 3. In one or more embodiments, the metal M comprises a transition metal. In one or more embodiments, the metal M comprises one or more of molybdenum (Mo), tungsten (W), cobalt (Co), titanium (Ti), zirconium (Zr), or hafnium (Hf). In embodiments where the metal silicide has the formula of MSiₓ and the metal M comprises one or more of molybdenum (Mo), tungsten (W), cobalt (Co), titanium (Ti), zirconium (Zr), or hafnium (Hf), the metal silicide has the formula of MoSiₓ, WSiₓ, CoSiₓ, TiSiₓ, ZrSiₓ, or HfSiₓ.

In one or more embodiments, the metal silicide is MoSi₂. In one or more embodiments, the metal silicide is WSi₂. In one or more embodiments, the metal silicide is CoSi₂. In one or more embodiments, the metal silicide is TiSi₂. In one or more embodiments, the metal silicide is ZrSi₂. In one or more embodiments, the metal silicide is HfSi₂.

The metal silicon nitride can be any compound that includes at least one metal atom, at least one silicon atom, and at least one nitrogen atom. In one or more embodiments, the metal silicon nitride has a formula MSiN where M is the metal. In one or more embodiments, the metal M comprises one or more of molybdenum (Mo), tungsten (W), cobalt (Co), titanium (Ti), zirconium (Zr), or hafnium (Hf). In embodiments where the metal silicon nitride has the formula of MSiN and the metal M comprises one or more of molybdenum (Mo), tungsten (W), cobalt (Co), titanium (Ti), zirconium (Zr), or hafnium (Hf), the metal silicon nitride has the formula of MoSiN, WSiN, CoSiN, TiSiN, ZrSiN, or HfSiN.

In one or more embodiments, the metal silicon nitride is MoSiN. In one or more embodiments, the metal silicon nitride is WSiN. In one or more embodiments, the metal silicon nitride is CoSiN. In one or more embodiments, the metal silicon nitride is TiSiN. In one or more embodiments, the metal silicon nitride is ZrSiN. In one or more embodiments, the metal silicon nitride is HfSiN.

The method 10 includes, at operation 14, depositing a metal nitride layer 140 on or directly on the interfacial layer 130. The metal nitride layer 140 can be deposited by any suitable deposition technique, including, but not limited to physical vapor deposition (PVD), chemical vapor deposition (CVD), or atomic layer deposition (ALD). In some embodiments, the metal nitride layer 140 is deposited by chemical vapor deposition (CVD). In some embodiments, the metal nitride layer 140 is deposited by atomic layer deposition (ALD). In some embodiments, the metal nitride layer 140 is conformally deposited by atomic layer deposition (ALD).

In some embodiments, the metal nitride layer 140 is deposited by a thermal process without the use of plasma.

In some embodiments, the metal nitride layer 140 is deposited by thermal chemical vapor deposition (CVD), i.e., without the use of plasma. In some embodiments, the metal nitride layer 140 is deposited by pulsed thermal chemical vapor deposition (CVD), where one of the metal-containing precursor and the nitrogen-containing reactant used to form the metal nitride layer 140 is pulsed constantly, and the other of the metal-containing precursor and the nitrogen-containing reactant is pulsed at a regular interval (i.e., pulsed intermittently).

In some embodiments, the metal nitride layer 140 is deposited by thermal atomic layer deposition (ALD), i.e., without the use of plasma. In some embodiments, the metal nitride layer 140 is deposited by pulsed thermal atomic layer deposition (ALD), where one of the metal-containing precursor and the nitrogen-containing reactant used to form the metal nitride layer 140 is pulsed constantly, and the other of the metal-containing precursor and the nitrogen-containing reactant is pulsed at a regular interval (i.e., pulsed intermittently).

The metal nitride layer 140 can be deposited at any suitable processing conditions, and the processing conditions may vary depending on the particular application in which the metal nitride layer 140 is used for.

The metal nitride can be any compound that includes at least one metal atom and at least one nitrogen atom. In some embodiments, the metal nitride layer 140 comprises titanium nitride (TiN). In one or more embodiments where the metal nitride layer 140 comprises titanium nitride (TiN), the metal nitride layer 140 is deposited by exposing the substrate 102 to a titanium-containing precursor, a nitrogen-containing reactant, and an inert gas. Any suitable titanium-containing precursor(s), any suitable nitrogen-containing reactant(s), and any suitable inert gas(es) can be used to form the metal nitride layer 140 comprising titanium nitride (TiN). In one or more embodiments, the titanium-containing precursor comprises titanium tetrachloride (TiCl₄). In one or more embodiments, the nitrogen-containing reactant comprises ammonia (NH₃). In one or more embodiments, the nitrogen-containing reactant comprises a mixture of ammonia (NH₃) and hydrogen (H₂).

In one or more embodiments, the titanium-containing precursor and the nitrogen-containing reactant are independently flowed at a flow rate of in a range of from 10 sccm to 100 sccm and the inert gas is flowed at a flow rate of in a range of from 5,000 sccm to 10,000 sccm. In one or more embodiments, the titanium-containing precursor and the nitrogen-containing reactant are independently flowed at a flow rate of 50 sccm and the inert gas is flowed at a flow rate of 8,000 sccm. In one or more embodiments, the inert gas comprises argon (Ar).

In one or more embodiments, the metal nitride layer 140 forms on the interfacial layer 130 on the bottom surface 109. In one or more embodiments, the metal nitride layer 140 on the interfacial layer 130 on the bottom surface 109 fills a portion of the at least one feature 110. In one or more unillustrated embodiments, a conductive material is formed on top of the metal nitride layer 140. Those of ordinary skill in the art, with the included description, will be able to implement appropriate functionality without undue experimentation.

The conductive material can be any suitable metallic material. In one or more embodiments, the conductive material comprises a transition metal.

In one or more unillustrated embodiments, the metal nitride layer 140 on the interfacial layer 130 on the bottom surface 109 fills the entirety of the at least one feature 110. Those of ordinary skill in the art, with the included description, will be able to implement appropriate functionality without undue experimentation.

In one or more embodiments where the metal nitride layer 140 on the interfacial layer 130 on the bottom surface 109 fills the entirety of the at least one feature 110, the metal nitride layer 140 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the metal nitride layer 140 on an atomic basis, comprises seams and/or voids. Advantageously, in one or more embodiments, the metal nitride layer 140 is free of seams and/or voids.

Accordingly, it will be appreciated by the skilled artisan that one or more additional operations needed to complete the processing of the substrate 102 are known to the skilled artisan and are within the scope of the disclosure without undue experimentation.

In one or more embodiments, the methods described herein comprise an optional post-processing operation 15. Operation 15 is denoted as optional in FIG. 1 by using the dashed outline in the process flow diagram. The optional post-processing operation 15 can be, for example, a process to modify film properties.

In some embodiments, the optional post-processing operation 15 comprises annealing the substrate 102. In some embodiments, the annealing process is performed at temperatures in the range of from 300° C. to 1000° C. The annealing environment of some embodiments comprises one or more of an inert gas or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the substrate 102 is annealed for a predetermined time in the range of about 15 seconds to about 90 minutes, or in the range of about 1 minute to about 60 minutes. In some embodiments, annealing the substrate increases the density, decreases the resistivity and/or increases the purity of the layers.

In one or more embodiments, one or more of the operations of the methods described herein are performed in situ in an integrated processing system, without an intervening vacuum break. In one or more embodiments, each of the operations of the methods described are performed in situ, without an intervening vacuum break. In one or more embodiments, one or more of the operations of the methods described herein are performed ex situ, such that one or more of the processes are performed with an intervening vacuum break.

The methods described herein can be performed any suitable processing system. The particular arrangement of processing chambers and components in the processing system can be varied depending on the processing system and should not be taken as limiting the scope of the disclosure.

Processes may generally be stored in the memory of a system controller as a software routine that, when executed by the processor, causes the processing system to perform one or more of the operations of any of the methods described herein. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the processing system operation such that one or more of the operations of any of the methods described herein are performed.

One or more embodiments of the disclosure are directed to a non-transitory computer readable medium including instructions that, when executed by a controller of a processing system (e.g., an integrated processing system), causes the processing system to perform one or more of the operations of any of the methods described herein. Additional embodiments of the disclosure are directed to a non-transitory computer readable medium including instructions that, when executed by a controller of a processing system (e.g., an integrated processing system), causes the processing system to perform the method 10.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing a semiconductor device, the method comprising:
depositing a molybdenum silicide (MoSi) layer directly on a substrate;
depositing an interfacial layer directly on the molybdenum silicide (MoSi) layer, the interfacial layer comprising a metal silicide having a formula of MSiₓ, where M is a metal and x is an integer in a range of from 1 to 3 or a metallic silicon nitride having a formula MSiN where M is the metal; and
depositing a metal nitride layer directly on the interfacial layer.

2. The method of claim 1, performed at a temperature in a range of from 20° C. to 600° C.

3. The method of claim 1, performed at a pressure in a range of from 5 torr to 50 Torr.

4. The method of claim 1, wherein depositing the interfacial layer comprises a thermal process without the use of plasma.

5. The method of claim 1, wherein the metal of the metal silicide and the metal of the metal silicon nitride is a transition metal.

6. The method of claim 5, wherein the metal of the metal silicide and the metal of the metal silicon nitride independently comprises titanium (Ti), zirconium (Zr), or hafnium (Hf).

7. The method of claim 1, wherein the interfacial layer has a thickness in a range of from 20 Angstroms to 100 Angstroms.

8. The method of claim 1, wherein the metal nitride layer comprises titanium nitride (TiN).

9. The method of claim 8, wherein the metal nitride layer comprising titanium nitride (TiN) is deposited by exposing the substrate to a titanium-containing precursor, a nitrogen-containing reactant, and an inert gas.

10. The method of claim 1, performed in situ in an integrated processing system.

11. The method of claim 1, wherein the semiconductor device is a logic device or a memory device.

12. A method of manufacturing a semiconductor device, the method comprising:
depositing a molybdenum silicide (MoSi) layer directly on a substrate having a top surface and at least one feature including sidewalls and a bottom surface;
depositing an interfacial layer directly on the molybdenum silicide (MoSi) layer, the interfacial layer comprising a metal silicide having a formula of MSiₓ, where M is a metal and x is an integer in a range of from 1 to 3 or a metal silicon nitride having a formula MSiN where M is the metal; and
depositing a metal nitride layer directly on the interfacial layer.

13. The method of claim 12, performed at a temperature in a range of from 20° C. to 600° C. and a pressure in a range of from 5 torr to 50 Torr.

14. The method of claim 12, wherein depositing the interfacial layer comprises a thermal process without the use of plasma.

15. The method of claim 12, wherein the interfacial layer has a thickness in a range of from 20 Angstroms to 100 Angstroms.

16. The method of claim 12, wherein the metal nitride layer comprises titanium nitride (TiN).

17. The method of claim 16, wherein the metal nitride layer comprising titanium nitride (TiN) is deposited by exposing the substrate to a titanium-containing precursor, a nitrogen-containing reactant, and an inert gas.

18. The method of claim 12, performed in situ in an integrated processing system.

19. The method of claim 12, wherein the semiconductor device is a logic device or a memory device.

20. A non-transitory computer readable medium including instructions, that, when executed by a controller of a processing system, causes the processing system to:
deposit a molybdenum silicide (MoSi) layer directly on a substrate;
deposit an interfacial layer directly on the molybdenum silicide (MoSi) layer, the interfacial layer comprising a metal silicide having a formula of MSiₓ, where M is a metal and x is an integer in a range of from 1 to 3 or a metal silicon nitride having a formula MSiN where M is the metal; and
deposit a metal nitride layer directly on the interfacial layer.
